(19) United States
(12) Patent Application Publication
(10) Pub. No.: US 2026/0140315 A1
(43) Pub. Date: May 21, 2026

(54) Method and Structure for High Precision Silicon Nitride Photonics Devices

(71) Applicant: Newport Fab, LLC dba Tower Semiconductor Newport Beach, Newport Beach, CA (US)

(72) Inventors: Edward Preisler, San Clemente, CA (US); Riichiro Mitsuhashi, Uozu City (JP)

(21) Appl. No.: 18/955,794

(22) Filed: Nov. 21, 2024

(51) Int. Cl. G02B 6/132; G02B 6/12; C23C 16/455

(52) U.S. Cl. CPC G02B 6/132; G02B 6/12019; C23C 16/45525; G02B 2006/12061

(57) ABSTRACT

In fabricating a semiconductor structure, a silicon nitride (SiN) layer is formed using atomic layer deposition (ALD). A SiN photonics device is formed from the SiN layer. The SiN photonics device is optically coupled to another device. A thickness of the SiN layer can be greater than or approximately equal to one hundred nanometers (100 nm). The SiN photonics device can be a multiplexer or a demultiplexer.

### BACKGROUND

Silicon photonics semiconductor wafers including silicon photonics devices are commonly utilized in a variety of applications, such as in telecommunications devices as transceivers for optical signals. Integration of silicon nitride (SiN) photonics devices in silicon photonics semiconductor wafers can enhance optical performance characteristics. However, conventional formation of SiN photonics devices can exhibit large variations across wafers and across batches, such as variations in thickness and refractive index, that result in some SiN photonics devices functioning improperly.

In one approach, active tuning features are introduced to correct for these variations. Such active tuning features consume valuable area and inhibit miniaturization, and can also cause other parasitic effects. Further, in order to accurately tune the desired SiN photonics device, complex driving/feedback circuitry and relatively high power consumption are often required.

Thus, there is a need in the art for high precision SiN photonics devices.

### SUMMARY

The present disclosure is directed to method and structure for high precision silicon nitride photonics devices, substantially as shown in and/or described in connection with at least one of the figures, and as set forth in the claims.

### BRIEF DESCRIPTION OF THE DRAWINGS

FIG. 1 illustrates a cross-sectional view of a portion of a semiconductor structure according to one implementation of the present application.

FIG. 2 illustrates a cross-sectional view of a portion of a semiconductor structure according to one implementation of the present application.

FIG. 3 illustrates a cross-sectional view of a portion of a semiconductor structure according to one implementation of the present application.

FIG. 4 illustrates a layout of an exemplary silicon nitride (SiN) photonics device corresponding to the semiconductor structure of FIG. 3 according to one implementation of the present application.

FIG. 5 illustrates an exemplary graph of output intensity versus wavelength.

FIG. 6 illustrates an exemplary graph of output intensity versus wavelength according to one implementation of the present application.

FIG. 7 illustrates a cross-sectional view of a portion of a semiconductor structure according to one implementation of the present application.

### DETAILED DESCRIPTION

The following description contains specific information pertaining to implementations in the present disclosure. The drawings in the present application and their accompanying detailed description are directed to merely exemplary implementations. Unless noted otherwise, like or corresponding elements among the figures may be indicated by like or corresponding reference numerals. Moreover, the drawings and illustrations in the present application are generally not to scale, and are not intended to correspond to actual relative dimensions. As used herein, “over” may refer to directly or indirectly over.

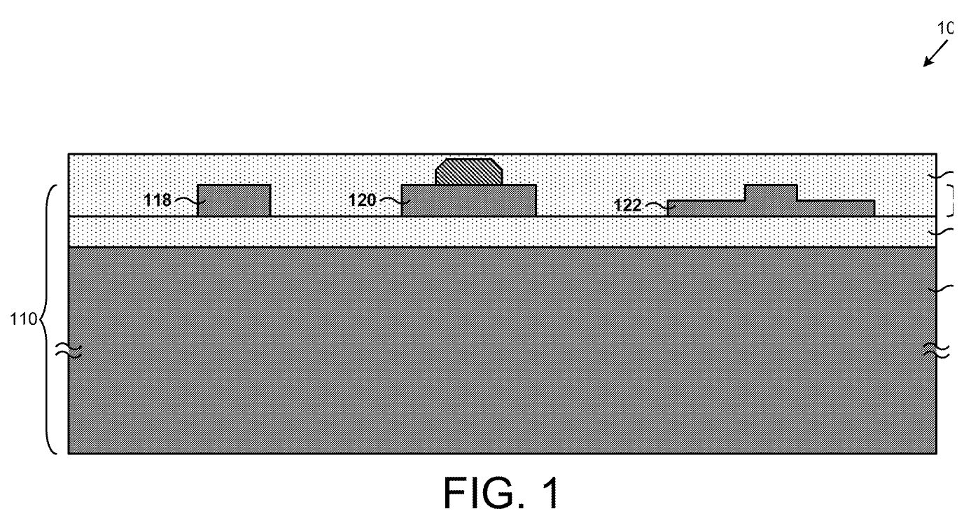

FIG. 1 illustrates a cross-sectional view of a portion of a semiconductor structure according to one implementation of the present application. As shown in FIG. 1, in semiconductor structure 100, substrate 110 is provided.

Semiconductor structure 100 includes substrate 110 having handle wafer 112, buried oxide (BOX) 114, and top semiconductor layer 116. In the present implementation, substrate 110 is a semiconductor-on-insulator (SOI) substrate. In providing substrate 110, a bonded and etch back SOI (BESOI) process can be used, as known in the art. Alternatively, as also known in the art, a SIMOX process or a “smart cut” process can also be used for providing substrate 110. In various implementations, substrate 110 may be another type of substrate other than an SOI substrate.

In one implementation, handle wafer 112 is undoped bulk silicon. In various implementations, handle wafer 112 can comprise germanium, group III-V material, or any other suitable handle material. In various implementations, handle wafer 112 has a thickness of approximately seven hundred microns (700 µm) or greater or less. In one implementation, a trap rich layer can be situated between handle wafer 112 and BOX 114. In various implementations, BOX 114 typically comprises silicon dioxide (SiO₂), but it may also comprise silicon nitride (SiN), or another insulator material. In various implementations, BOX 114 has a thickness of approximately one micron (1 µm) to approximately three microns (3 µm) or greater or less. In one implementation, top semiconductor layer 116 includes monocrystalline silicon. In various implementations, top semiconductor layer 116 can comprise germanium, group III-V material, or any other semiconductor material. In various implementations, top semiconductor layer 116 has a thickness of approximately three hundred nanometers (200 nm) to approximately five hundred nanometers (500 nm) or greater or less.

In one implementation, substrate 110 is a group IV substrate. As used herein, the phrase “group IV” refers to a semiconductor material that includes at least one group IV element such as silicon (Si), germanium (Ge), and carbon (C), and may also include compound semiconductors such as silicon germanium (SiGe) and silicon carbide (SiC), for example. “Group IV” also refers to semiconductor materials that include more than one layer of group IV elements, or doping of group IV elements to produce strained group IV materials, and may also include group IV based composite substrates such as silicon on insulator substrates, separation by implantation of oxygen (SIMOX) process substrates, and silicon on sapphire (SOS) substrates, for example. In one implementation, substrate 110 is a semiconductor-on-insulator (SOI) wafer having a diameter of approximately two hundred millimeters (200 mm). In various implementations, substrate 110 can be glass, quartz, or sapphire.

As shown in FIG. 1, in semiconductor structure 100, photonics devices 118, 120, and 122 are situated in top semiconductor layer 116 of substrate 110. Top semiconductor layer 116 includes photonics devices 118, 120, and 122 on BOX 114. In semiconductor structure 100, photonics devices 118, 120, and 122 are formed by patterning top semiconductor layer 116. Portions of top semiconductor layer 116 are removed to isolate photonics devices 118, 120, and 122 from the rest of top semiconductor layer 116. In other implementations, dedicated isolation structures can be used. Photonics devices 118, 120, and 122 are any type of photonics devices. In one implementation, photonics device 118 can be a waveguide, photonics device 120 can be a photodiode comprising germanium grown over a portion top semiconductor layer 116, and photonics device 122 can be an electro-absorption modulator (EAM). In various implementations, photonics devices 118, 120, and 122 can be any other type of photonics device, such as a laser, a grating coupler, an interferometer, a phase shifter, or an optical switch. Photonics devices 118, 120, and 122 can be formed, for example, by patterning, doping, and/or performing other processing on top semiconductor layer 116 of substrate 110.

Photonics devices 118, 120, and 122 can have different dimensions and/or can include different structures than those shown in FIG. 1. Additional photonic devices (not shown) can be situated in top semiconductor layer 116. Electronics devices (not shown), such as a transistor, an operational amplifier, a driver, a filter, a mixer, or a diode, can also be formed in top semiconductor layer 116. In various implementations, semiconductor structure 100 can include an active circuit (not shown) comprising multiple active devices, or comprising passive devices in combination with at least one active device.

In various implementations, photonics devices 118, 120, and 122 can be situated over substrate 110, instead of (or in addition to) in substrate 110. For example, substrate 110 can be a glass substrate and photonics device 118 can be a waveguide comprising Pockels material situated over substrate 110. In various implementations, Pockels material can comprise lithium niobate (LiNbO₃), lithium tantalate (LiTa), potassium dihydrogen phosphate (KDP), deuterated potassium dihydrogen phosphate (DKDP), rubidium titanyl phosphate (RTP), potassium titanyl phosphate (KTP), potassium titanyl arsenate (KTA), barium borate (BBO), barium titanate (BTO), ammonium dihydrogen phosphate (ADP), cadmium telluride (CdTe), organic materials which demonstrate a strong Pockels effect, or any other suitable Pockels material.

Interlayer dielectric (ILD) 124 is situated over photonics devices 118, 120, and 122 in top semiconductor layer 116 and over BOX 114. ILD 124 insulates photonics devices 118, 120, and 122, and aids subsequent processing. In various implementations, ILD 124 can comprise borophosphosilicate glass (BPSG), tetra-ethyl ortho-silicate (TEOS), SiO₂, SiN, silicon oxynitride (SiON), or another dielectric. ILD 124 can be formed by depositing and planarizing a dielectric layer, for example, using chemical mechanical polishing (CMP).

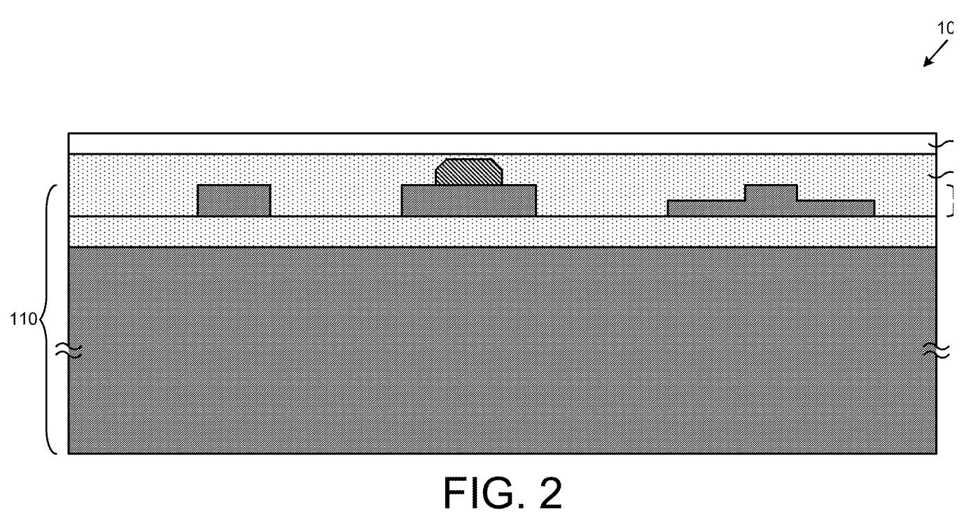

FIG. 2 illustrates a cross-sectional view of a portion of a semiconductor structure according to one implementation of the present application. As shown in FIG. 2, in semiconductor structure 102, SiN layer 126 is formed. SiN layer 126 is situated over top semiconductor layer 116 of substrate 110 and on ILD 124.

SiN layer is formed using atomic layer deposition (ALD), or any species thereof, such as thermal ALD or plasma enhanced ALD. The ALD SiN deposition cycle can alternatingly pulse a silicon precursor and a nitrogen precursor with purges in between. For example, a silane and a plasma containing nitrogen can be utilized as precursors.

SiN layer 126 is a thick ALD film. In one implementation, a thickness of SiN layer 126 is greater than or approximately equal to one hundred nanometers (100 nm). In one implementation, SiN layer 126 can have a thickness of approximately four hundred nanometers (400 nm). The thickness generally corresponds to a subsequently formed SiN photonics device, and will be chosen based on factors such as the type of photonics device and the wavelength of light the device is designed to interact with. Because SiN layer 126 is a thick ALD film, it takes a long time to form. In various implementations, forming SiN layer 126 can take approximately forty eight hours (48 hrs) or longer, since the ALD SiN deposition cycle can be approximately thirty second (30 s) to approximately one minute (1 min), and the growth per cycle (GPC) can be approximately half an angstrom (0.5 Å) to approximately two angstroms (2.0 Å). For contrast, the growth rate of a CVD SiN layer can be approximately tens to hundreds of nanometers per minute.

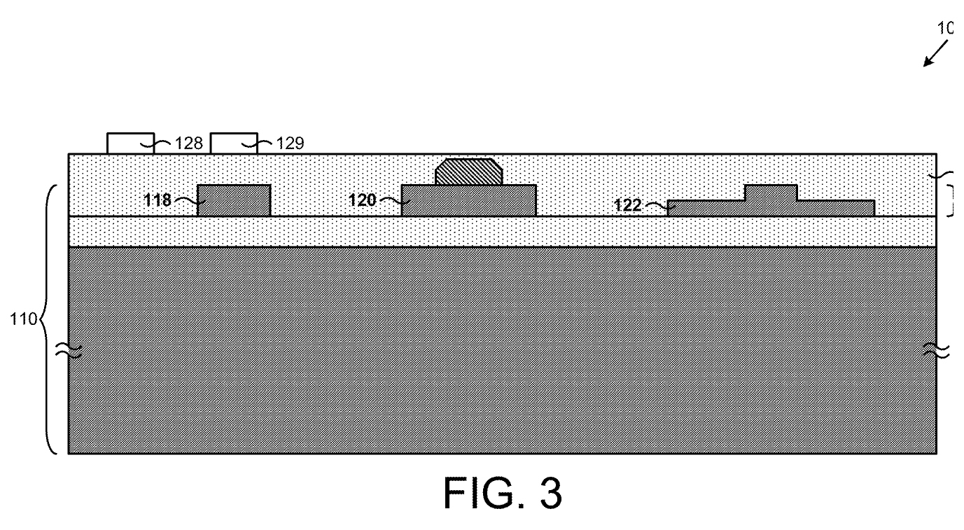

FIG. 3 illustrates a cross-sectional view of a portion of a semiconductor structure according to one implementation of the present application. A shown in FIG. 3, in semiconductor structure 104, SiN photonics devices 128 and 129 are formed from SiN layer 126 (shown in FIG. 2).

SiN photonics devices 128 and 129 are situated on ILD 124 over top semiconductor layer 116 of substrate 110. SiN photonics devices 128 and 129 can be formed from SiN layer 126 using any technique known in the art. For example, a patterned mask can be formed over SiN layer 126, and then a dry plasma etch may be performed using the mask in order to form SiN photonics devices 128 and 129. The dry plasma etch may be selective to nitride and stop at ILD 124.

SiN photonics devices 128 and 129 are configured to manipulate light in semiconductor structure 104. In various implementations, the cross-sectional portions of SiN photonics devices 128 and 129 visible in FIG. 3 can each be a portion of a larger SiN photonics device, such as a waveguide, an interferometer, a multiplexer, a demultiplexer, a directional coupler, a splitter/combiner, a resonator, or any other SiN photonics device known in the art.

SiN photonics devices 128 and 129 are optically coupled to other devices in semiconductor structure 104. In the implementation of FIG. 3, SiN photonics device 129 is shown to overlie photonics device 118 in top semiconductor layer 116, which can correspond to an optical transition region of semiconductor structure 104. A thickness of ILD 124 or other material between photonics device 118 and SiN photonics device 129 can be chosen to influence coupling therebetween. However, it is understood that SiN photonics device 129 need not be aligned with photonics devices 118. SiN photonics devices 128 and 129 may optically couple to any of photonics devices 118, 120, and 120, or to other devices not shown.

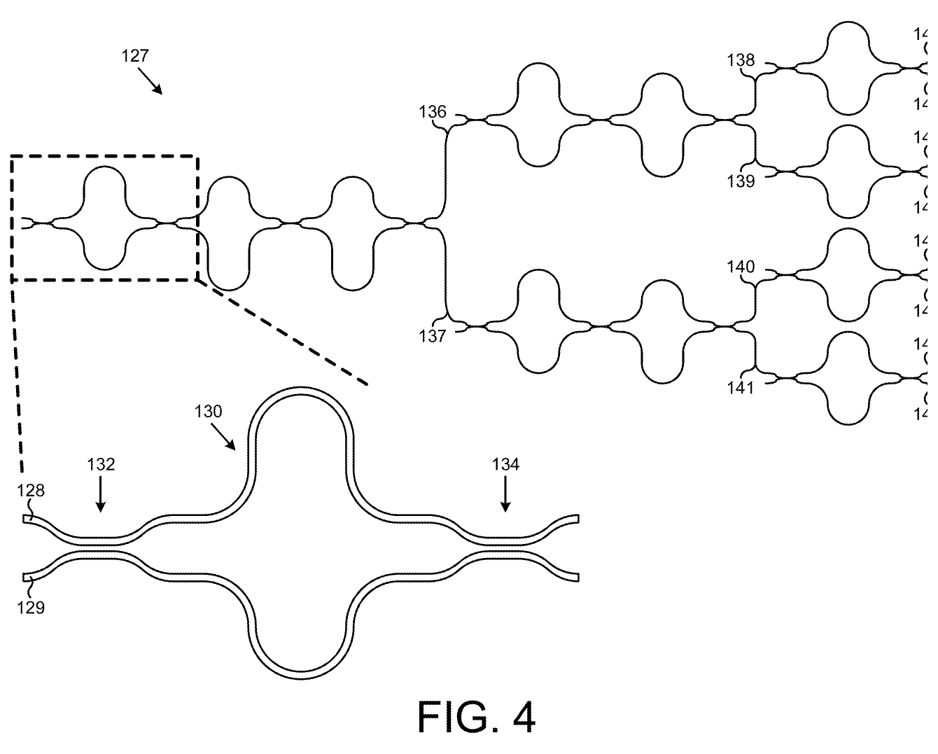

FIG. 4 illustrates a layout of an exemplary SiN photonics device 127 corresponding to semiconductor structure 104 of FIG. 3 according to one implementation of the present application. FIG. 4 represents an exemplary layout in the plane containing SiN photonics devices 128 and 129 in FIG. 3.

SiN photonics devices 128 and 129 are part of larger SiN photonics device 127. In particular, SiN photonics devices 128 and 129 are part of waveguide arms that make up a Mach-Zehnder interferometer (MZI) 130 and directional couplers 132 and 134. As shown in FIG. 4, multiple cascaded MZIs and directional couplers make up SiN photonics device 127.

In the present implementation, SiN photonics device 127 is a demultiplexer. In this implementation, SiN photonics device 128 or 129 can act as an input to SiN photonics device 127. SiN photonics device 128 or 129 can be optically coupled to another device, such as a laser, a grating coupler, a modulator, or a waveguide, in the semiconductor structure in order to receive an input light signal. The input light signal can include eight wavelengths (or wavelength ranges). A first stage of SiN photonics device 127 includes three cascaded MZIs 130 with directional couplers at each end. The first stage can be configured to demultiplex the input light signal into four wavelengths at each of first stage outputs (or second stage inputs) 136 and 137. A second stage of SiN photonics device 127 includes two sets of two cascaded MZIs 130 with directional couplers at each end. The second stage can be configured to demultiplex its inputs into two wavelengths at each of second stage outputs (or third stage inputs) 138, 139, 140, and 141. A third stage of SiN photonics device 127 includes four sets of MZIs 130 with directional couplers at each end. The third stage can be configured to demultiplex its inputs into a single wavelength (or wavelength range) at each of outputs 142, 143, 144, 145, 146, 147, 148, and 149. Outputs 142, 143, 144, 145, 146, 147, 148, and 149 of SiN photonics device 127 can be optically coupled to another device, such as a photodiode, a waveguide, or a grating coupler, in the semiconductor structure.

In the present implementation, SiN photonics device 127 is a passive device. SiN photonics device 127 only requires a light input. SiN photonics device 127 does not utilize another input, such as an input that takes advantage of thermo-optic or electro-optic effects. In particular, no heaters are utilized over or in proximity to arms of MZI 130 in order to tune SiN photonics device 127. SiN photonics device 127 is also reversible and can be a multiplexer that functions in the reverse manner from the demultiplexer described above. SiN photonics device 127 can also be another type of passive photonics device other than a (de)multiplexer.

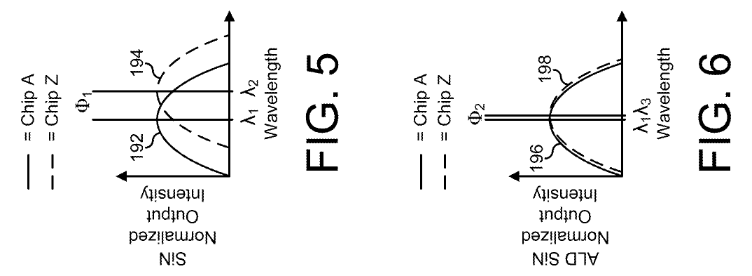

FIG. 5 illustrates an exemplary graph of output intensity versus wavelength. The intensity-wavelength graph in FIG. 5 represents the normalized intensity of light output by conventional SiN photonics devices, such as SiN demultiplexers comprising CVD SiN, plotted over wavelength.

In the graph, traces 192 and 194 represent corresponding outputs from SiN photonics devices in different chips or dies from the same wafer. The solid line trace 192 corresponding to “Chip A” represents an output of a chip or die with the lowest center wavelength (wavelength where intensity peaks). The dashed line trace 194 corresponding to “Chip Z” represents a corresponding output of a chip or die with the highest center wavelength.

A peak intensity of “Chip A” is shown to occur at wavelength λ₁. A peak intensity of “Chip Z” is shown to occur at wavelength λ₂. Phase shift Φ₁ represents the difference between wavelength λ₁ and wavelength λ₂. This means that corresponding outputs of SiN photonics devices from the same wafer that should be identical instead exhibit some variation. In one implementation, phase shift Φ₁ can be approximately ten nanometers (10 nm). Such a variation among chips or dies can detrimentally result in an output being interpreted as the wrong signal. Accordingly, SiN photonics devices may need to be active devices, for example, including phase shifters and tuning circuitry, to properly demultiplex a signal into a predetermined channel.

FIG. 6 illustrates an exemplary graph of output intensity versus wavelength according to one implementation of the present application. The intensity-wavelength graph in FIG. 6 represents the normalized intensity of light output by SiN photonics devices according to the present application, such as SiN demultiplexer 127 in FIG. 4 comprising ALD SiN, plotted over wavelength. Accordingly, the graph in FIG. 6 is described below with reference to SiN demultiplexer 127 in FIG. 4.

Traces 196 and 198 represent corresponding outputs from SiN photonics devices 127 in different chips or dies from the same wafer. The solid line trace 196 corresponding to “Chip A” represents an output, such as output 142 in FIG. 4, of a chip or die with the lowest center wavelength. The dashed line trace 198 corresponding to “Chip Z” represents a corresponding output, such as output 142 in FIG. 4, of a chip or die with the highest center wavelength.

Again, a peak intensity of “Chip A” is shown to occur at wavelength λ₁. However, a peak intensity of “Chip Z” is shown to occur at wavelength λ₃ that is much closer to λ₁. Phase shift Φ₂ represents the difference between wavelength λ₁ and wavelength λ₃. This indicates that corresponding outputs 142 of SiN photonics devices 127 exhibit significantly reduced variation. In one implementation, phase shift Φ₂ can be approximately one nanometer (1 nm) or less. Such a variation among chips or dies can be within a channel tolerance and can beneficially ensure output signals are correctly interpreted. SiN photonics devices 127 need not rely on phase shifters and other tuning circuitry to properly demultiplex a signal into a predetermined channel, and SiN photonics devices 127 can be passive devices.

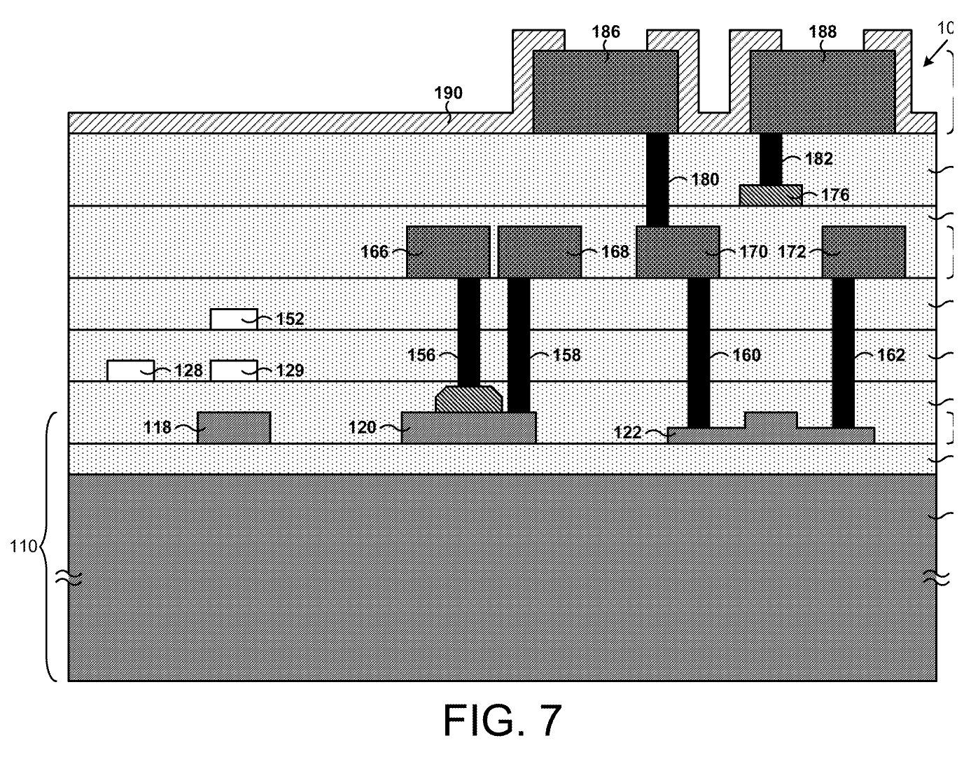

FIG. 7 illustrates a cross-sectional view of a portion of a semiconductor structure according to one implementation of the present application. As shown in FIG. 7, in semiconductor structure 106, additional processing is completed. The additional processing includes forming ILD 150, SiN photonics device 152, ILD 154, contacts 156, 158, 160, and 162, interconnect metal layer 164, interconnect metal segments 166, 168, 170, and 172, ILD 174, heater 176, ILD 178, vias 180 and 182, interconnect metal layer 184, interconnect metal segments 186 and 188, and passivation layer 190.

ILD 154 is formed over ILD 150 and SiN photonics devices 128 and 129. SiN photonics device 152 is formed over ILD 154. SiN photonics device 152 can be formed in a similar manner to SiN photonics devices 128 and 129. That is, another SiN layer can be formed over ILD 154 using ALD, and then patterned in order to form SiN photonics device 152. In various implementations, more SiN photonics devices can be formed from the ALD SiN layer than shown in FIG. 7. SiN photonics device 152 can increase capabilities or improve routing of semiconductor structure 106. In the present implementation, SiN photonics device 152 is aligned over and optically coupled to SiN photonics device 129. In various implementations, SiN photonics device 152 can be optically coupled to other devices (not shown) in semiconductor structure 106. Notably, SiN photonics device 152 experiences improved precision, as described above with respect to FIG. 6.

Contacts 156, 158, 160, and 162 are situated in ILDs 124, 150, and 154. Contacts 156 and 158 connect to photonics device 120 in top semiconductor layer 116. Contacts 160 and 162 connect to photonics device 122 in top semiconductor layer 116. In one implementation, a metal is deposited in contact holes and then planarized with ILD 154, for example, using CMP, thereby forming contacts 156, 158, 160, and 162. In an alternative implementation, a damascene process is used to form contacts 156, 158, 160, and 162. In various implementations, contacts 156, 158, 160, and 162 can comprise tungsten (W), copper (Cu), or aluminum (Al).

Interconnect metal layer 164 includes interconnect metal segments 166, 168, 170, and 172. Interconnect metal segments 166, 168, 170, and 172 are formed over and electrically coupled to contacts 156, 158, 160, and 162 respectively. In one implementation, a metal layer is deposited over ILD 154 and contacts 156, 158, 160, and 162, and then segments thereof are etched, thereby forming interconnect metal segments 166, 168, 170, and 172. In an alternative implementation, a damascene process is used to form interconnect metal segments 166, 168, 170, and 172. In various implementations, interconnect metal segments 166, 168, 170, and 172 can comprise W, Al, or Cu.

Contacts 156, 158, 160, and 162 and interconnect metal segments 166, 168, 170, and 172 together route electricity to/from SiN photonics devices 120 and 122. Although contacts 156, 158, 160, and 162 and interconnect metal segments 166, 168, 170, and 172 are illustrated as separate formations in FIG. 7, in other implementations they may be parts of the same formation. Semiconductor structure 106 can include other contacts and other interconnect metal segments not shown in FIG. 7.

ILD 174 is formed over ILD 154 and interconnect metal segments 166, 168, 170, and 172 of interconnect metal layer 164. Heater 176 is formed over ILD 174 in ILD 178 at a level where conventionally no metal interconnect exists. As shown in FIG. 7, heater 176 is not situated at the same level as interconnect metal layers 164 or 184, it is situated between. A layer utilized to form heater 176 can be formed in a dedicated step, where a metal interconnect is not also formed from the same layer. Heater 176 is situated over and in proximity to photonics device 122. Heater 176 and semiconductor structure 106 can be configured to thermally tune photonics device 122, which can be, for example, a modulator. Heater 176 and semiconductor structure 106 can configured such that generated heat is dissipated before reaching SiN photonics devices 128, 129, and 152.

ILD 178 is formed over ILD 174 and heater 176. Via 180 is situated in ILDs 178 and 174, and connects interconnect metal segment 170 in interconnect metal layer 164 to interconnect metal segment 186 in interconnect metal layer 184. Likewise, via 182 is situated in ILD 178, and connects heater 176 to interconnect metal segment 188 in interconnect metal layer 184. Interconnect metal layer 184 includes interconnect metal segments 186 and 188. Interconnect metal segments 186 and 188 are formed over and electrically coupled to vias 180 and 182 respectively.

ILDs 150, 154, 174, and 178 can be formed in a similar manner to ILD 124, as described above. Vias 180 and 182 can be formed in a similar manner to contacts 156, 158, 160, and 162, as described above. Interconnect metal segments 186 and 188 can be formed in a similar manner to interconnect metal segments 166, 168, 170, and 172, as described above.

Passivation layer 190 is formed over and on sidewalls of interconnect metal segments 186 and 188, and over ILD 178. Passivation layer 190 can be formed by conformal deposition, for example, by PVD or CVD techniques. In various implementations, passivation layer 190 can include a semiconductor-based dielectric such as SiO₂, SiN, or SiON. In various implementations, passivation layer 190 can have a thickness of approximately fifty angstroms (50 Å) to approximately two hundred angstroms (200 Å). In various implementations, passivation layer 190 comprises multiple passivation layers. As shown in FIG. 7, windows are formed in passivation layer 190 exposing portions of interconnect metal segments 186 and 188. Thus, the exposed portions of interconnect metal segments 186 and 188 can function as bond pads for external electrical connections, for example, to photonics device 122 and heater 176.

From the above description it is manifest that various techniques can be used for implementing the concepts described in the present application without departing from the scope of those concepts. Moreover, while the concepts have been described with specific reference to certain implementations, a person of ordinary skill in the art would recognize that changes can be made in form and detail without departing from the scope of those concepts. As such, the described implementations are to be considered in all respects as illustrative and not restrictive. It should also be understood that the present application is not limited to the particular implementations described above, but many rearrangements, modifications, and substitutions are possible without departing from the scope of the present disclosure.

1. A method comprising:
forming a first silicon nitride (SiN) layer using atomic layer deposition (ALD);
forming a first SiN photonics device from said first SiN layer;
wherein said first SiN photonics device is optically coupled to another device.

2. The method of claim 1, wherein a thickness of said first SiN layer is greater than or approximately equal to one hundred nanometers (100 nm).

3. The method of claim 1, wherein said first SiN photonics device is selected from the group consisting of a waveguide, a multiplexer, a demultiplexer, and a Mach-Zehnder interferometer (MZI).

4. The method of claim 1, wherein said another device is a waveguide, electro-absorption modulator (EAM), laser, or photodiode.

5. The method of claim 1, wherein said first SiN layer is formed over an interlayer dielectric (ILD).

6. The method of claim 1, wherein said first SiN layer is formed over a top semiconductor layer of a semiconductor-on-insulator (SOI) substrate.

7. The method of claim 1, wherein said another device is situated in a top semiconductor layer of a semiconductor-on-insulator (SOI) substrate.

8. The method of claim 1, further comprising forming a second SiN layer using ALD over said first SiN photonics device;
wherein said another device is a second SiN photonics device formed from said second SiN layer.

9. A method comprising:
forming a first silicon nitride (SiN) layer using atomic layer deposition (ALD);
forming a multiplexer or a demultiplexer from said first SiN layer, said multiplexer or said demultiplexer comprising cascaded Mach-Zehnder interferometers (MZIs).

10. The method of claim 9, wherein a thickness of said first SiN layer is greater than or approximately equal to one hundred nanometers (100 nm).

11. The method of claim 9, wherein said multiplexer or said demultiplexer is a passive device.

12. The method of claim 9, wherein said multiplexer or said demultiplexer is optically coupled to another device situated in a top semiconductor layer of a semiconductor-on-insulator (SOI) substrate.

13. The method of claim 9, further comprising:
forming a second SiN layer using ALD over said multiplexer or said demultiplexer;
forming a SiN photonics device from said second SiN layer;
wherein said SiN photonics device is optically coupled to said multiplexer or said demultiplexer.

14. A semiconductor structure comprising:
a first silicon nitride (SiN) photonics device comprising an atomic layer deposited silicon nitride having a thickness greater than or approximately equal to one hundred nanometers (100 nm);
said first SiN photonics device being optically coupled to another device.

15. The semiconductor structure of claim 14, wherein said first SiN photonics device is a passive device.

16. The method of claim 14, wherein said first SiN photonics device is selected from the group consisting of a waveguide, a multiplexer, a demultiplexer, and a Mach-Zehnder interferometer (MZI).

17. The method of claim 14, wherein said another device is a waveguide, electro-absorption modulator (EAM), laser, or photodiode.

18. The method of claim 14, wherein said first SiN photonics device is situated over an interlayer dielectric (ILD).

19. The semiconductor structure of claim 14, wherein said another device is situated in a top semiconductor layer of a semiconductor-on-insulator (SOI) substrate.

20. The semiconductor structure of claim 14, wherein said another device is a second SiN photonics device over said first SiN photonics device.
